(19) United States
(12) Patent Application Publication
(10) Pub. No.: US 2026/0213618 A1
(43) Pub. Date: Jul. 23, 2026

(54) DRIVING DEVICE AND ELECTRIC DEVICE

(71) Applicant: HONDA MOTOR CO., LTD., Tokyo (JP)

(72) Inventor: Tatsunoshin ISHIKAWA, Saitama (JP)

(21) Appl. No.: 19/380,305

(22) Filed: Nov. 5, 2025

(30) Foreign Application Priority Data
Jan. 17, 2025 (JP) 2025-006656

(51) Int. Cl. H02K 9/06; B60L 15/00; H02K 7/00; H02K 9/22; H02K 11/33; H05K 7/20

(52) U.S. Cl. CPC H02K 9/06; B60L 15/007; H02K 7/003; H02K 7/006; H02K 9/227; H02K 11/33; H05K 7/209; H05K 7/20909; B60L 2200/10

(57) ABSTRACT

A driving device includes a rotation shaft and configured to drive the rotation shaft. The driving device includes a cooling passage formed on an outer circumference of the driving device and extending along an axial direction of the rotation shaft, and a plurality of heat generating portions arranged adjacent to the cooling passage. The plurality of heat generating portions includes at least one first heat generating portion and at least one second heat generating portion spaced apart from the first heat generating portion in the axial direction. The plurality of heat generating portions is arranged so that centers thereof do not overlap with each other when viewed in the axial direction.

### TECHNICAL FIELD

The present invention relates to a driving device and an electric device that include a rotation shaft and drive the rotation shaft.

### BACKGROUND ART

In recent years, efforts to realize a low-carbon or carbon-free society have been gaining momentum, and research and development of electrification technologies is being conducted for vehicles, aircraft, and the like to reduce CO₂ emissions and improve energy efficiency.

A technology for cooling a driving device that includes a plurality of heat generating portions and a rotation shaft and drives the rotation shaft is known. For example, the drive device described in FIGS. 13 to 15 of JP2023-163874A includes two electric motors that rotate the rotation shaft, two inverters that supply power to the electric motors, and a fan that generates airflow to cool the two electric motors and the two inverters. A stator of the electric motor includes coils. The coil generates heat when energized. A switch module of the inverter also generates heat when energized. In JP2023-163874A, the stator of the electric motor and the switch module of the inverter correspond to the heat generating portions. In the drive device of JP2023-163874A, the fan, the two adjacent electric motors, and the two adjacent inverters are aligned along the axial direction of the rotation shaft. The drive unit includes a motor housing that accommodates two electric motors, and an inverter housing that accommodates two inverters.

On the outer circumferential surface of the motor housing, plate-shaped fins projecting in the radial direction are provided corresponding to each of the two electric motors. The airflow generated by the fan flows in the axial direction along the outer circumferential surface of the motor housing and cools the two electric motors. Further, on the outer circumferential surface of the inverter housing, plate-shaped fins projecting in the radial direction are provided corresponding to each of the two inverters. The airflow generated by the fan flows in the axial direction along the outer circumferential surface of the inverter housing and cools the two inverters.

In the drive device shown in FIGS. 13 to 15 of JP2023-163874A, the two electric motors and the two inverters are aligned along the axial direction in which the air flows. Accordingly, the airflow heated by cooling the fins corresponding to the electric motor on the upstream side of the airflow cools the fins corresponding to the electric motor on the downstream side, thereby reducing the efficiency of cooling the heat generating portion (stator) of the electric motor on the downstream side. Further, the airflow heated by cooling the fins corresponding to the inverter on the upstream side of the airflow cools the fins corresponding to the inverter on the downstream side, thereby reducing the efficiency of cooling the heat generating portion (switch module) of the inverter on the downstream side.

### SUMMARY OF THE INVENTION

In view of the above background, an object of the present invention is to efficiently cool all heat generating portions in a driving device including a plurality of heat generating portions, and to contribute to the improvement in energy efficiency.

To achieve such an object, one aspect of the present invention provides a driving device (16) including a rotation shaft (34) and configured to drive the rotation shaft, the driving device comprising: a cooling passage (P) formed on an outer circumference and extending along an axial direction (X) of the rotation shaft; and a plurality of heat generating portions (46) arranged adjacent to the cooling passage. The plurality of heat generating portions includes at least one first heat generating portion (46A) and at least one second heat generating portion (46B) spaced apart from the first heat generating portion in the axial direction, and the plurality of heat generating portions is arranged so that centers thereof do not overlap with each other when viewed in the axial direction.

According to this aspect, a refrigerant flows through the cooling passage in the axial direction. When viewed in the axial direction, the centers of the plurality of heat generating portions are arranged so as not to overlap with each other. This prevents the refrigerant that has received heat from one of the heat generating portions from flowing toward the center of another heat generating portion. Accordingly, the refrigerant that has received heat from one of the heat generating portions is prevented from cooling another heat generating portion. Accordingly, the driving device (the electric device) can efficiently cool all the heat generating portions.

In the above aspect, preferably, each of the plurality of heat generating portions includes a plurality of heat generating elements (56A, 56B, 57A, 57B), and the plurality of heat generating portions is arranged at equal intervals in a circumferential direction when viewed in the axial direction.

According to this aspect, each heat generating portion includes the plurality of heat generating elements. Further, when viewed in the axial direction, all of the heat generating portions are arranged at equal intervals in the circumferential direction. This prevents all the heat generating elements in all the heat generating portions from being disposed closely together when viewed in the axial direction. Accordingly, all the heat generating elements can be cooled efficiently.

In the above aspect, preferably, the driving device further comprises a plurality of electric motors configured to drive the rotation shaft, and a plurality of controllers configured to generate heat when energized to control operation of the plurality of electric motors, and the plurality of heat generating portions includes the plurality of controllers.

According to this aspect, the driving device can be cooled reliably and efficiently.

In the above aspect, preferably, the at least one first heat generating portion comprises a plurality of first heat generating portions, and the at least one second heat generating portion comprises a plurality of second heat generating portions, the plurality of heat generating portions includes the plurality of first heat generating portions aligned with each other in the axial direction, and the plurality of second heat generating portions spaced apart from the plurality of first heat generating portions in the axial direction and aligned with each other in the axial direction. The plurality of first heat generating portions is arranged at equal intervals in a circumferential direction, and the plurality of second heat generating portions is arranged at equal intervals in the circumferential direction.

According to this aspect, the plurality of first heat generating portions is arranged at equal intervals in the circumferential direction. This prevents heat from one of the first heat generating portions from being transferred to another first heat generating portion. Accordingly, each of the first heat generating portions can be cooled efficiently. Further, the plurality of second heat generating portions is arranged at equal intervals in the circumferential direction. This prevents heat from one of the second heat generating portions from being transferred to another second heat generating portion. Accordingly, each of the second heat generating portions can be cooled efficiently. Accordingly, all the first heat generating portions and the second heat generating portions can be cooled efficiently.

In the above aspect, preferably, each of the plurality of heat generating portions is arranged so as not to overlap with each other when viewed in the axial direction.

According to this aspect, each of the plurality of heat generating portions is arranged so as not to overlap with each other when viewed in the axial direction. The refrigerant flows through the cooling passage along the axial direction. This prevents the refrigerant that has received heat from one of the heat generating portions from flowing toward another heat generating portion. Accordingly, the refrigerant that has received heat from one of the heat generating portions is prevented from cooling another heat generating portion. Accordingly, the driving device can efficiently cool all the heat generating portions.

In the above aspect, preferably, the cooling passage includes heat receiving areas (HA) adjacent to the plurality of heat generating portions and non-heat receiving areas (CA) adjacent to the heat receiving areas in a circumferential direction, and each of the heat receiving areas is provided with a plurality of heat dissipation fins (45, 45A, 45B, 45C).

According to this aspect, the heat dissipation fins promote cooling of the heat generating portions adjacent to the heat receiving area, and all the heat generating portions can be cooled efficiently.

In the above aspect, preferably, each of the heat receiving areas and each of the non-heat receiving areas are provided with the plurality of heat dissipation fins, and density of the heat dissipation fins in each of the heat receiving areas is greater than the density of the heat dissipation fins in each of the non-heat receiving areas.

According to this aspect, the heat dissipation fins promote cooling of the heat generating portions adjacent to the heat receiving area, and all the heat generating portions can be cooled efficiently.

In the above aspect, preferably, the plurality of heat dissipation fins includes a plurality of guiding fins (45A) that extends radially outward of the driving device and extends continuously in the axial direction from one end to another end of the driving device.

According to this aspect, the guiding fin extends continuously in the axial direction from one end to another end of the driving device. Accordingly, in the cooling passage, the refrigerant is prevented from flowing across the guiding fins in a direction intersecting the axial direction. Accordingly, in the cooling passage, the refrigerant flowing between the two adjacent guiding fins flows along the axial direction between the two adjacent guiding fins. This prevents the refrigerant that has received heat from one of the heat generating portions from flowing in a direction intersecting the axial direction toward another heat generating portion. In other words, the refrigerant that has received heat from the heat generating portion is prevented from cooling another heat generating portion on the downstream side. Accordingly, all the heat generating portions can be cooled efficiently.

In the above aspect, preferably, in each of the heat receiving areas, at least one auxiliary fin (45B) is provided between the two adjacent guiding fins, and length of the auxiliary fin in the axial direction is shorter than length of the guiding fins in the axial direction.

According to this aspect, the auxiliary fins promote cooling of the heat generating portions adjacent to the heat receiving area, and all the heat generating portions can be cooled efficiently.

In the above aspect, preferably, the driving device further comprises a propeller (35) fixed to the rotation shaft and configured to generate a propulsion airflow that flows in a direction in which a refrigerant flows in the cooling passage.

According to this aspect, a portion of the propulsion airflow F flows into the cooling passage, so that all the heat generating portions can be cooled efficiently.

To achieve such an object, one aspect of the present invention provides an electric device (16) comprising: a cooling passage (P) formed on an outer circumference and extending along a first direction (X); and a plurality of heat generating portions (46) arranged adjacent to the cooling passage. The plurality of heat generating portions includes at least one first heat generating portion (46A) and at least one second heat generating portion (46B) spaced apart from the first heat generating portion in the first direction, and the plurality of heat generating portions is arranged so that centers thereof do not overlap with each other when viewed in the first direction.

According to this aspect, the refrigerant flows through the cooling passage along a first direction. The plurality of heat generating portions is arranged so that the centers thereof do not overlap with each other when viewed in the first direction. This prevents the refrigerant that has received heat from the heat generating portions from flowing toward the center of another heat generating portion. Accordingly, the refrigerant that has received heat from one of the heat generating portions is prevented from cooling another heat generating portion. Accordingly, the electric device can efficiently cool all the heat generating portions.

Thus, according to the above aspects, in the driving device including the plurality of heat generating portions, it is possible to efficiently cool all the heat generating portions.

### BRIEF DESCRIPTION OF THE DRAWING(S)

FIG. 1 is a perspective view showing an aircraft according to a first embodiment;

FIG. 2 is a schematic cross-sectional view showing a propulsion unit according to the first embodiment;

FIG. 3 is a schematic cross-sectional view of a driving device according to the first embodiment;

FIG. 4 is an overall circuit diagram of an electric motor and a controller according to the first embodiment;

FIG. 5 is a circuit diagram showing a configuration of the controller according to the first embodiment;

FIG. 6 is a perspective view of a housing and the controller according to the first embodiment;

FIG. 7 is a sectional view taken along line VII-VII of FIG. 3;

FIG. 8 is a sectional view taken along line VIII-VIII of FIG. 3;

FIG. 9 is a development view of an outer circumference of the housing according to the first embodiment;

FIG. 10 is a cross-sectional view of a housing according to a second embodiment;

FIG. 11 is a development view of the housing according to the second embodiment; and

FIG. 12 is a development view of a housing according to a third embodiment.

### DETAILED DESCRIPTION OF THE INVENTION

### First Embodiment

### An Aircraft 1

In the following, an aircraft 1 according to a first embodiment of the present invention will be described with reference to the drawings. In the drawings and the following description, directions such as forward, rearward, left, right, up, and down are directions defined relative to the aircraft 1.

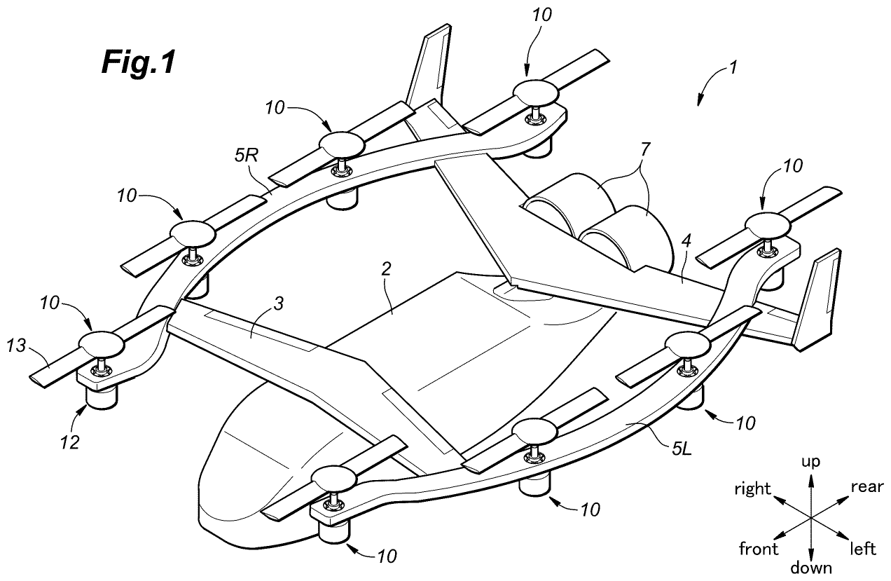

FIG. 1 is a perspective view showing the aircraft 1 according to the first embodiment. The aircraft 1 is an electric vertical take-off and landing aircraft (eVTOL aircraft) capable of taking off and landing vertically. The aircraft 1 includes a body 2 extending in the front-and-rear direction, a front wing 3 extending in the lateral direction and connected to the front portion of the body 2, a rear wing 4 extending in the lateral direction and connected to the rear portion of the body 2, a left arm 5L extending in the front-and-rear direction and connecting the left end of the front wing 3 to the left side portion of the rear wing 4, and a right arm 5R extending in the front-and-rear direction and connecting the right end of the front wing 3 to the right side portion of the rear wing 4.

A cabin (not shown) for an occupant to board is provided in the front portion of the body 2. Left and right propulsion units 7 (described in detail later) for applying the forward propulsion force to the aircraft 1 are provided at the rear end of the body 2.

The left arm 5L and the right arm 5R are each provided with a plurality of (for example, four) lift units 10 for applying the ascending and descending forces to the aircraft 1. The plurality of lift units 10 is arranged at intervals in the front-and-rear direction. Each lift unit 10 includes a lift drive device 12 and a lift rotor 13 attached to the lift drive device 12. The lift drive device 12 includes an electric motor (not shown), and is configured to rotate the lift rotor 13 by the driving force of the electric motor.

### The Propulsion Unit 7

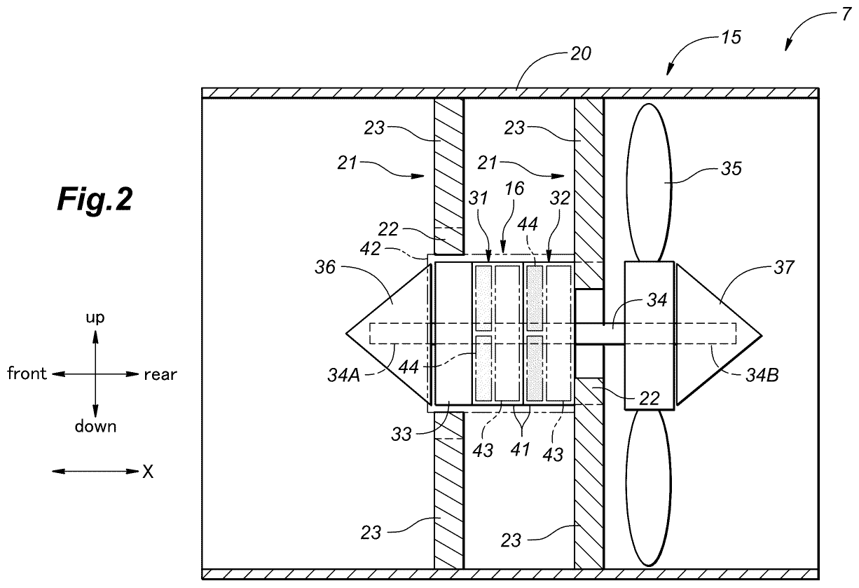

FIG. 2 is a schematic cross-sectional view of the propulsion units 7. Each propulsion unit 7 includes a support body 15 and a driving device 16 supported by the support body 15.

The support body 15 is fixed to the rear end of the body 2 (see FIG. 1). The support body 15 includes a cylindrical nacelle 20 extending in the front-and-rear direction, and front and rear mount frames 21 fixed to the inner circumferential surface of the nacelle 20. Each mount frame 21 includes an annular hub 22 that is concentric with the nacelle 20, and a plurality of spokes 23 extending radially from the outer circumferential surface of the hub 22 and connected to the inner circumferential surface of the nacelle 20.

### The Driving Device 16

As shown in FIG. 2, the driving device 16 includes the first drive unit 31, a second drive unit 32, a fan 33, a shaft 34 (a rotation shaft) extending in the front-and-rear direction and rotatably supported by the driving device 16, and a propeller 35 fixed to the rear portion of the shaft 34. The driving device 16 is accommodated in the nacelle 20. The driving device 16 is fixed to the hub 22 of the front and rear mount frames 21. The driving device 16 drives the shaft 34. The driving device 16 is an example of an electric device.

Each of the first drive unit 31 and the second drive unit 32 rotatably supports the shaft 34 about the axis, causing the shaft 34 to rotate. The first drive unit 31 is fixed to the hub 22 of the front mount frame 21. The second drive unit 32 is fixed to the hub 22 of the rear mount frame 21.

The fan 33 generates a cooling airflow W that cools the first drive unit 31 and the second drive unit 32. The cooling airflow W flows rearward.

The shaft 34 extends along the axial direction X (the first direction) of the shaft 34. A conical front cover 36 the diameter of which increases toward the rear is fixed to a first end 34A (the front end) of the shaft 34 on the first drive unit 31 side. The front cover 36 is arranged behind the center portion of the propeller 35. A conical rear cover 37 the diameter of which increases toward the front is fixed to a second end 34B (the rear end) of the shaft 34 on the second drive unit 32 side.

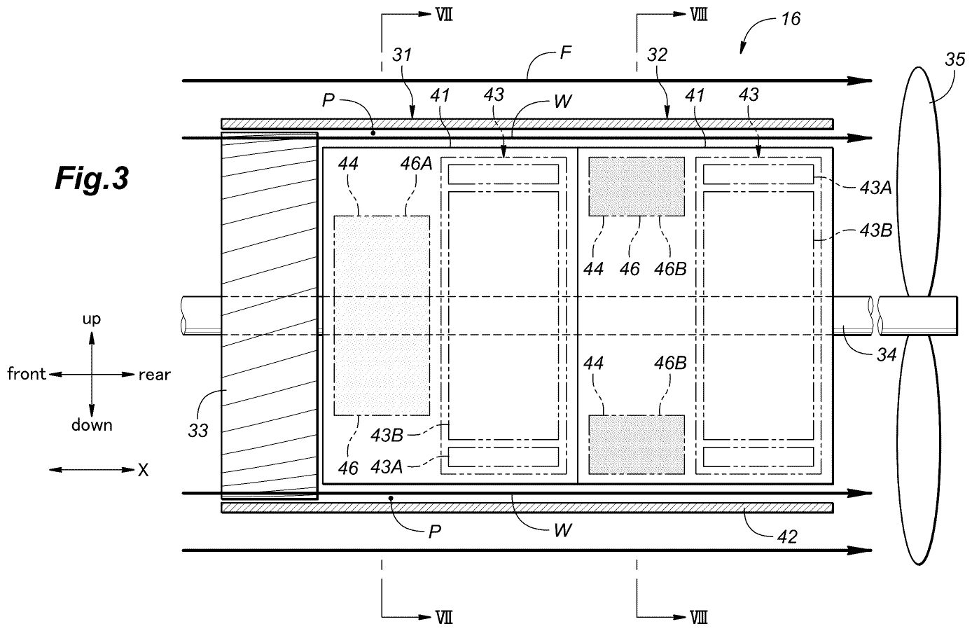

The propeller 35 is configured to rotate integrally with the shaft 34 according to the rotation of the shaft 34, thereby generating a propulsion airflow F (see FIG. 3) that flows along the axial direction X (rearward). The propeller 35 generates the propulsion airflow F, thereby applying the forward propulsion force to the aircraft 1.

### The First Drive Unit 31, the Second Drive Unit 32

As shown in FIG. 2, each of the first drive unit 31 and the second drive unit 32 includes a housing 41, a pair of front and rear lids (not shown) attached to the front and rear of the housing 41, a duct 42, an electric motor 43, and two controllers 44.

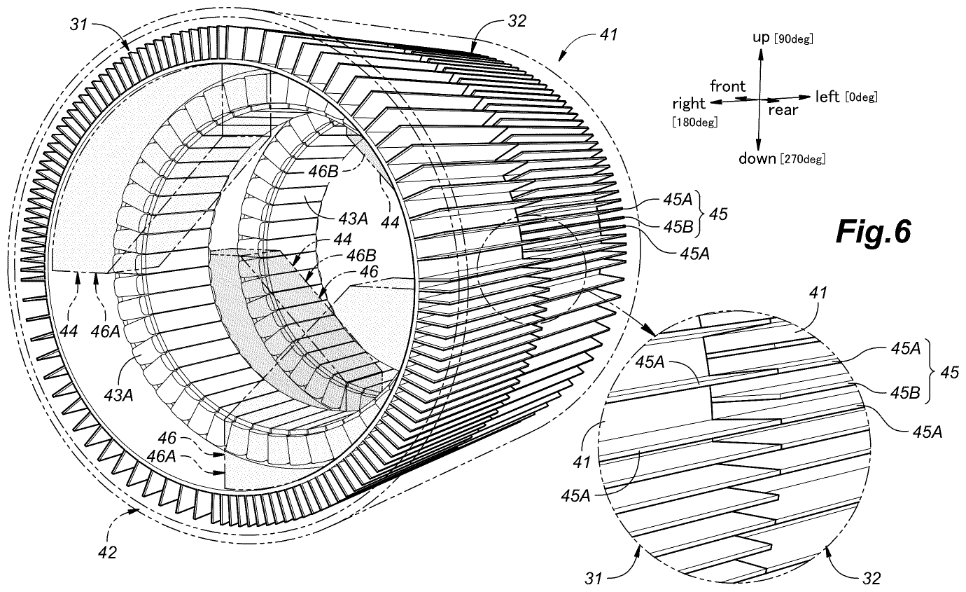

FIG. 3 is a schematic cross-sectional view of the driving device 16. As shown in FIG. 3, the housing 41 is formed in a cylindrical shape that extends in the front-and-rear direction on the outer circumference of the shaft 34. The outer circumferential surface of the housing 41 is provided with a plurality of heat dissipation fins 45 (see FIG. 6) extending radially outward of the driving device 16 and extending along the axial direction X. Each heat dissipation fin 45 is formed integrally with the housing 41.

The pair of front and rear lids (not shown) is formed in a disk shape. The pair of front and rear lids is arranged at the front and rear of the housing 41 to close the front and rear openings of the housing 41. The lid and the housing 41 are joined together in a known manner. The lid and the housing 41 may be joined by fastening with bolts and nuts, by riveting, by adhesive bonding, by welding, or by a combination thereof.

The duct 42 covers the outer circumference of the housing 41 and is formed in a cylindrical shape extending along the axial direction X. The duct 42 of the first drive unit 31 and the duct 42 of the second drive unit 32 are integrally formed and extend to the outer circumference of the fan 33. The duct 42 is attached to the housing 41 in a known manner. For example, the lid may have a protrusion extending radially outward, and the duct 42 may be fixed to the protrusion. Alternatively, the housing 41 may have a protrusion extending radially outward of the outer circumference, and the duct 42 may be fixed to the protrusion. The fixing of the protrusion of the lid to the duct 42, or the fixing of the protrusion of the housing 41 to the duct 42, may be performed using bolts and nuts, rivets, adhesive, welding, or a combination thereof.

Between the outer circumferential surface of the housing 41 and the duct 42, a cooling passage P that extends continuously along the front-and-rear direction from the front end to the rear end of the housing 41 is formed. The cooling passage P extends in the circumferential direction and also in the axial direction X of the shaft 34. Air (a refrigerant) flows through the cooling passage P.

When the fan 33 rotates, the cooling airflow W flows rearward along the axial direction X (the direction in which the propulsion airflow F generated by the propeller 35 flows). The cooling airflow W enters the cooling passage P and flows rearward through the cooling passage P along the axial direction X. The electric motor 43 and the controller 44 are arranged adjacent to the cooling passage P, and the heat generated by the electric motor 43 and the heat generated by the controller 44 are transferred to the cooling passage P. The heat generated by the electric motor 43 and the heat generated by the controller 44 are cooled through the cooling passage P.

The electric motor 43 includes a stator 43A and a rotor 43B and is connected to the controller 44. The electric motor 43 is a three-phase AC motor of an inner rotor type. The stator 43A is fixed to the inside of the housing 41 and is formed in a cylindrical shape. The rotor 43B is arranged inside the stator 43A, faces the stator 43A with a gap therebetween, and is formed integrally with the shaft 34. The stator 43A includes a plurality of coils (not shown), and the rotor 43B includes a plurality of permanent magnets (not shown) fixed to the outer circumference. A magnetic force of the plurality of coils of the stator 43A and a magnetic force of the permanent magnet of the rotor 43B generate a rotational force that rotates the rotor 43B about the axis of the shaft 34. The rotor 43B rotates together with the shaft 34. This causes the electric motor 43 to drive the shaft 34. In the stator 43A, a plurality of coils generate heat. The stator 43A is arranged adjacent to the cooling passage P.

The controller 44 includes a case (not shown) and an inverter accommodated in the case. As will be described later, the controller 44 is connected to the electric motor 43 and controls the operation of the electric motor 43. Each of the first drive unit 31 and the second drive unit 32 includes two controllers 44. The controller 44 is arranged adjacent to the cooling passage P. The controller 44 generates heat when energized to control the operation of the electric motor 43. The controller 44 is a heat generating portion 46. The heat generating portion 46 is a device that generates an especially large amount of heat in the driving device 16.

The controller 44 is mounted to the housing 41 at the front side of the electric motor 43 in a known manner. The controller 44 may be mounted to the housing 41 by fastening with bolts and nuts, by riveting, by adhesion, by welding, or by a combination thereof.

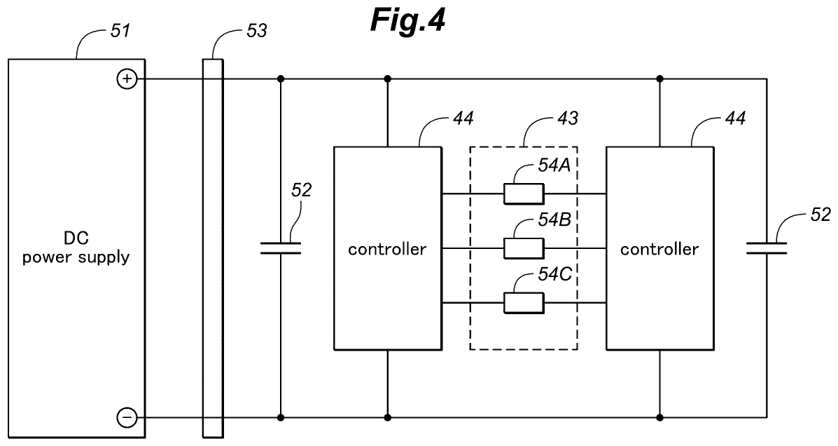

FIG. 4 is an overall circuit diagram of the electric motor 43 and the controller 44 for driving the electric motor 43. As shown in FIG. 4, in each of the first drive unit 31 and the second drive unit 32, two controllers 44 and two capacitors 52 are connected to a DC power supply 51 provided outside the driving device 16 via a DC input connector 53. The DC power supply 51 may be a battery such as a primary battery or a secondary battery, or may be a generator. The DC input connector 53 is provided with a positive terminal and a negative terminal of the DC power supply 51.

The two controllers 44 and the two capacitors 52 are connected in parallel to the positive and negative terminals of the DC power supply 51. Each of the two controllers 44 is connected to AC output terminals 54A to 54C of the electric motor 43. Each controller 44 includes the inverter that converts direct current input from the DC power supply 51 into alternating current. The capacitor 52 smooths the DC current input from the DC power supply 51 to the controller 44.

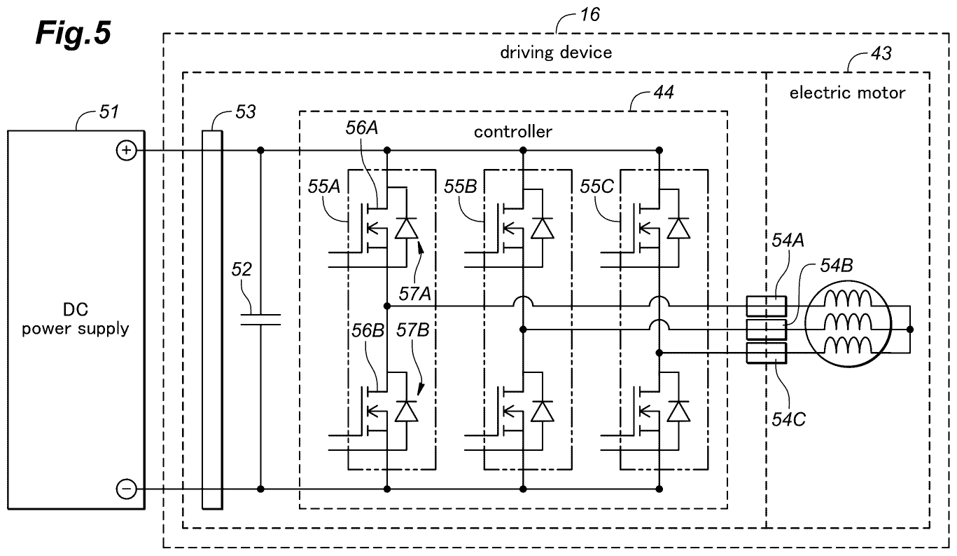

FIG. 5 is a circuit diagram showing a configuration of the controller 44. As shown in FIG. 5, the controller 44 includes power modules 55A to 55C. The power modules 55A to 55C are connected in parallel to the positive and negative terminals of the DC power supply 51 via the DC input connector 53. The power modules 55A to 55C are connected to the AC output terminals 54A to 54C of the electric motor 43, respectively.

Each of the three power modules 55A to 55C includes switching elements 56A and 56B and the freewheel diodes 57A and 57B. The switching element 56A and the freewheel diode 57A are connected in parallel to the positive terminal of the DC power supply 51 and one of the AC output terminals 54A to 54C of the electric motor 43. The switching element 56B and the freewheel diode 57B are connected in parallel to the negative terminal of the DC power supply 51 and one of the AC output terminals 54A to 54C of the electric motor 43.

As described above, the controller 44 includes the power modules 55A to 55C. Each of the power modules 55A to 55C includes the switching elements 56A and 56B and the freewheel diodes 57A and 57B. Accordingly, the controller 44 includes six switching elements (three switching elements 56A and three switching elements 56B) and six freewheel diodes (three freewheel diodes 57A and three freewheel diodes 57B). The switching elements 56A and 56B are semiconductor elements such as IGBTs and MOSFETs. The switching elements 56A and 56B and the freewheel diodes 57A and 57B usually generate a larger amount of heat than the capacitor 52. The switching elements 56A and 56B and the freewheel diodes 57A and 57B are elements that generate relatively large amounts of heat and are referred to as “heat generating elements.” It should be noted that elements other than the switching element and the freewheel diode may also be referred to as “heat generating elements.”

The controller 44 is the heat generating portion 46 including twelve (plural) heat generating elements (the switching elements 56A and 56B, the freewheel diodes 57A and 57B). There is no limitation on the number of heat generating elements included in the heat generating portion (the controller 44). The heat generating portion (the controller 44) is not required to include six switching elements (three switching elements 56A and three switching elements 56B) and six freewheel diodes (three freewheel diodes 57A and three freewheel diodes 57B).

The capacitor 52 is connected in parallel with the power modules 55A to 55C with respect to the DC power supply 51. The capacitor 52 smooths the DC current input from the DC power supply 51 to the power modules 55A to 55C (the controller 44). The capacitor 52 protects the power modules 55A to 55C by smoothing pulse current (pulse-shaped current caused by surge voltage) generated in the direct current input from the DC power supply 51 to the power modules 55A to 55C. The capacitor 52 may be a capacitor unit including a plurality of capacitors connected in parallel.

FIG. 6 is a perspective view of the housing 41 and the controller 44. The two controllers 44 of the first drive unit 31 are referred to as “first heat generating portion 46A,” and the two controllers 44 of the second drive unit 32 are referred to as “second heat generating portion 46B.” The driving device 16 includes two first heat generating portions 46A and two second heat generating portions 46B spaced apart in the axial direction X from the two first heat generating portions 46A. “Heat generating portion 46” is a collective term for the first heat generating portion 46A and the second heat generating portion 46B. Each of the first heat generating portion 46A and the second heat generating portion 46B has a plurality of heat generating elements (the switching elements 56A and 56B, the freewheel diodes 57A and 57B).

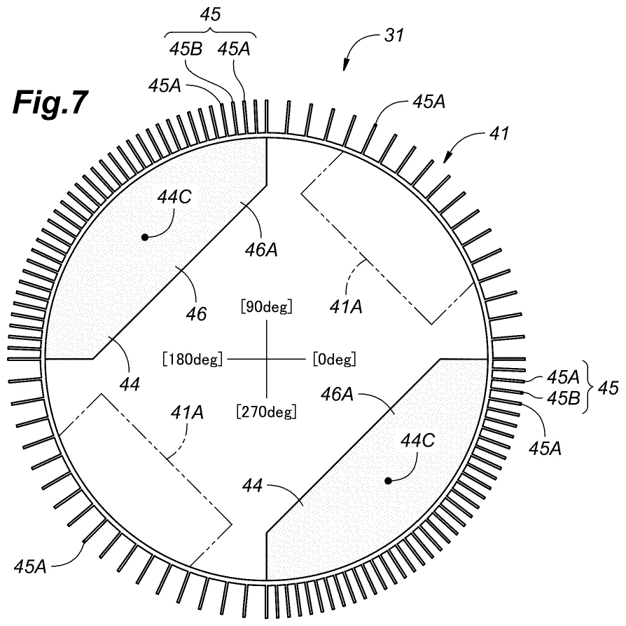

FIG. 7 is a sectional view of the first drive unit 31 taken along line VII-VII of FIG. 3. The two first heat generating portions 46A of the first drive unit 31 are arranged at equal intervals in the circumferential direction. In a low heat area 41A between the two first heat generating portions 46A in the circumferential direction, components such as the capacitor 52 that generate less heat than the heat generating portion 46 (referred to as “low heat portion”) are arranged. By arranging the two first heat generating portions 46A and the two low heat areas 41A in this manner, the length of the first drive unit 31 in the axial direction X can be shortened.

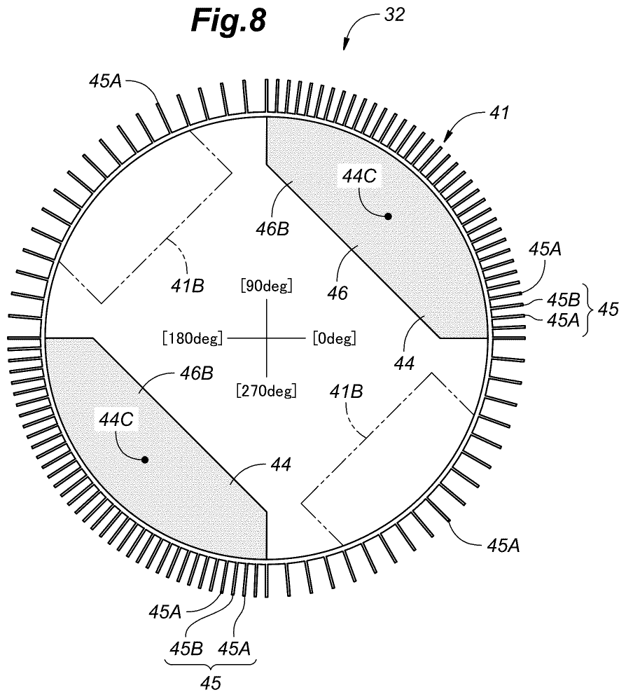

FIG. 8 is a sectional view of the second drive unit 32 taken along line VIII-VIII of FIG. 3. The two second heat generating portions 46B of the second drive unit 32 are arranged at equal intervals in the circumferential direction. In the low heat area 41B between the two second heat generating portions 46B in the circumferential direction, the low heat portion such as the capacitor 52 is arranged. By arranging the two second heat generating portions 46B and the two low heat areas 41B in this manner, the length of the second drive unit 32 in the axial direction X can be shortened.

As shown in FIGS. 6 to 8, the first drive unit 31 and the second drive unit 32 are circumferentially offset by 90 degrees from each other. The driving device 16 includes four controllers 44 (the heat generating portions 46). When viewed in the axial direction X, the four controllers 44 are arranged at equal intervals in the circumferential direction. Accordingly, when viewed in the axial direction X, the centers 44C (indicated by capital letters 44C in the drawing) of the four controllers 44 are arranged so as not to overlap with each other. Further, when viewed in the axial direction X, the four controllers 44 are arranged so as not to overlap with each other.

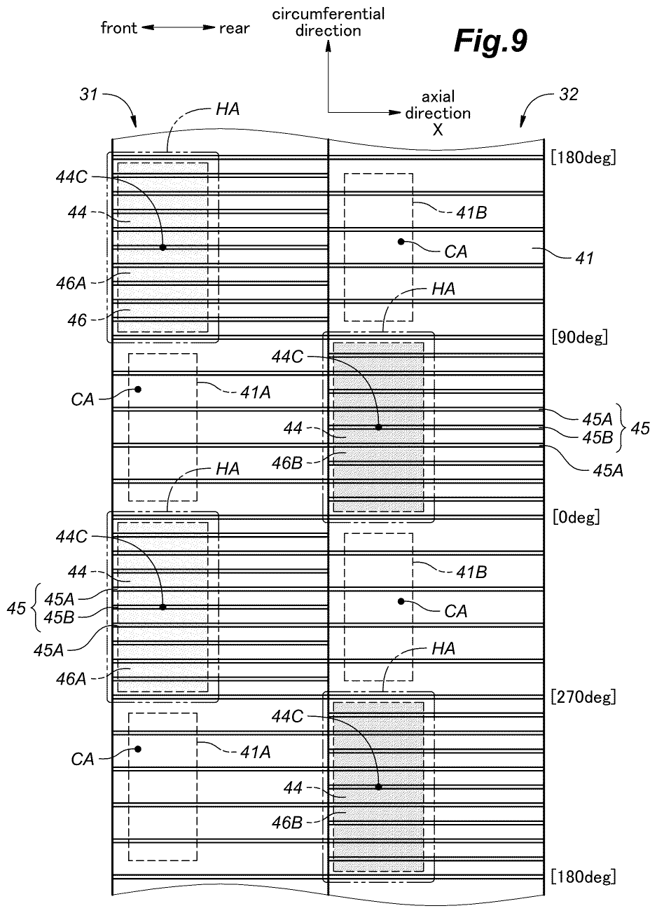

FIG. 9 is an exploded view of the outer circumference of the housing 41. In the cooling passage P, the area adjacent to the heat generating portions 46 (the controller 44) is referred to as “heat receiving area HA,” and the area other than the heat receiving area HA that is adjacent to the heat receiving area HA in the circumferential direction is referred to as “non-heat receiving area CA.” The heat receiving area HA is an area that needs more cooling than the non-heat receiving area CA. The heat dissipation fins 45 are provided in the heat receiving area HA and the non-heat receiving area CA. The heat receiving area HA may be an area surrounded by the outline of the heat generating portion 46 (the controller 44) projected onto the outer circumferential surface of the housing 41, when the outline of the heat generating portion 46 (the controller 44) is projected radially outward onto the outer circumferential surface of the housing 41. The non-heat receiving area CA is located in the circumferential direction of the heat receiving area HA, and may be an area that is not included in the heat receiving area HA.

The housing 41 is provided with, as the heat dissipation fins 45, a plurality of guiding fins 45A and a plurality of auxiliary fins 45B arranged between the two adjacent guiding fins 45A. There is no limitation on the number of guiding fins 45A and the auxiliary fins 45B.

As shown in FIG. 6, each of the plurality of guiding fins 45A is formed in a plate shape that extends radially outward of the housing 41 of the first drive unit 31 and the second drive unit 32, and extends continuously in the axial direction X from one end to another end of the driving device 16. Further, the radially outer ends of the guiding fins 45A are in contact with the duct 42. In the present embodiment, the portions of the guiding fins 45A provided in the first drive unit 31 and the second drive unit 32 are adjacent to each other so as to be continuous. The two portions may be in contact with each other. The two portions may be integrally formed. The guiding fins 45A are arranged at equal intervals in the circumferential direction of the housing 41.

Each of the plurality of auxiliary fins 45B is formed in a plate shape that extends radially outward of the housing 41 of the first drive unit 31 or the second drive unit 32, and extends continuously in the axial direction X from one end to another end of the housing 41. As shown in FIG. 9, the length of the auxiliary fin 45B in the axial direction X is half the length of the guiding fin 45A in the axial direction X, and is shorter than the length of the guiding fin 45A in the axial direction X. Further, the radially outer ends of the guiding fins 45A are in contact with the duct 42.

As shown in FIG. 9, the guiding fin 45A is provided in the heat receiving area HA and the non-heat receiving area CA. On the other hand, the auxiliary fin 45B is provided in the heat receiving area HA. That is, the guiding fin 45A and the auxiliary fin 45B are provided in the heat receiving area HA. On the other hand, the guiding fin 45A is provided in the non-heat receiving area CA but the auxiliary fin 45B is not provided in the non-heat receiving area CA. In the non-heat receiving area CA, the auxiliary fin 45B does not pass through the low heat areas 41A and 41B. This causes the density of the heat dissipation fins 45 in the heat receiving area HA to be higher than the density of the heat dissipation fins 45 in the non-heat receiving area CA. Here, the density refers to the number of heat dissipation fins 45 per unit area.

As shown in FIG. 3, the cooling airflow W generated by the rotation of the fan 33 flows into the cooling passage P. The cooling airflow W flows rearward through the cooling passage P along the axial direction X (the direction in which the propulsion airflow F generated by the propeller 35 flows). That is, in FIG. 9, the cooling airflow W flows from left to right.

Next, the effects of the driving device 16 will be described.

Air flows through the cooling passage P along the axial direction X. As shown in FIGS. 7 to 9, when viewed in the axial direction X, the centers 44C of the four heat generating portions 46 are arranged so as not to overlap with each other. This prevents the air that has received heat from the heat generating portions 46 of the first drive unit 31 from flowing toward the center 44C of another heat generating portion 46 of the second drive unit 32. Accordingly, the air that has received heat from one of the heat generating portions 46 is prevented from cooling another heat generating portion 46. Accordingly, the driving device 16 (the electric device) can efficiently cool all the heat generating portions 46. Further, the driving device 16 can be cooled efficiently.

As shown in FIG. 5, each of the heat generating portions 46 (the controller 44) includes twelve heat generating elements (the switching elements 56A and 56B, the freewheel diodes 57A and 57B). As shown in FIGS. 6 and 9, when viewed in the axial direction X, all the heat generating portions 46 are arranged at equal intervals in the circumferential direction. This prevents all the heat generating elements of all the heat generating portions 46 from being disposed closely together when viewed in the axial direction X. Accordingly, all the heat generating elements can be cooled efficiently.

The heat generating portion 46 (the first heat generating portion 46A, the second heat generating portion 46B) is the controller 44 that generates heat when energized to control the operation of the electric motor 43. Accordingly, the driving device 16 can be cooled efficiently.

The two first heat generating portions 46A are arranged at equal intervals in the circumferential direction. This prevents the heat from one first heat generating portion 46A from being transferred to another first heat generating portion 46A. Accordingly, all the first heat generating portions 46A can be cooled efficiently. The two second heat generating portions 46B are arranged at equal intervals in the circumferential direction. This prevents the heat from one second heat generating portion 46B from being transferred to another second heat generating portion 46B. Accordingly, all the second heat generating portions 46B can be cooled efficiently. Accordingly, all the first heat generating portions 46A and the second heat generating portions 46B can be cooled efficiently.

When viewed in the axial direction X, each of the four heat generating portions 46 is arranged so as not to overlap with each other. Air flows through the cooling passage P along the axial direction X. This prevents the air that has received heat from the heat generating portion 46 in the first drive unit 31 from flowing toward another heat generating portion 46 in the second drive unit 32. Accordingly, the air that has received heat from one of the heat generating portions 46 is prevented from cooling another heat generating portion 46. Accordingly, the driving device 16 (the electric device) can efficiently cool all the heat generating portions 46. Further, the driving device 16 can be cooled efficiently.

Each heat receiving area HA is provided with a plurality of heat dissipation fins 45. Accordingly, the heat dissipation fins 45 promote cooling of the heat generating portions 46 adjacent to the heat receiving area HA, so that all the heat generating portions 46 can be cooled efficiently.

The density of the heat dissipation fins 45 in the heat receiving area HA is greater than the density of the heat dissipation fins 45 in the non-heat receiving area CA. Accordingly, the heat dissipation fins 45 promote cooling of the heat generating portions 46 adjacent to the heat receiving area HA, so that all the heat generating portions 46 can be cooled efficiently.

The plurality of guiding fins 45A is provided. The guiding fin 45A extends continuously in the axial direction X from one end to another end of the driving device 16. Accordingly, in the cooling passage P, air is prevented from flowing across the guiding fins 45A in a direction intersecting the axial direction X. Accordingly, in the cooling passage P, the air flowing between the two adjacent guiding fins 45A flows along the axial direction X between the two adjacent guiding fins 45A. This prevents the air that has received heat from the heat generating portions 46 of the first drive unit 31 from flowing in a direction intersecting the axial direction X toward another heat generating portion 46 of the second drive unit 32. That is, the air that has received heat from the heat generating portions 46 is prevented from cooling another heat generating portion 46 on the downstream side. This allows all the heat generating portions 46 to be cooled efficiently.

In the heat receiving area HA, the auxiliary fin 45B is provided between two adjacent guiding fins 45A. Accordingly, the auxiliary fins 45B promote cooling of the heat generating portions 46 adjacent to the heat receiving area HA, so that all the heat generating portions 46 can be cooled efficiently.

Further, pressure loss occurs due to the auxiliary fin 45B. Inside the cooling passage P, the air tends to bypass a portion where the pressure loss is high. The guiding fin 45A is formed in a plate shape that extends radially outward of the driving device 16 and extends continuously in the axial direction X from one end to another end of the driving device 16. This prevents air from flowing across the guiding fins 45A in a direction intersecting the axial direction X. The air flowing between the two adjacent guiding fins 45A flows along the axial direction X between the two adjacent guiding fins 45A. This prevents the air flowing through the cooling passage P from bypassing the auxiliary fins 45B. Accordingly, a sufficient amount of air can be ensured to flow through the heat receiving area HA. Accordingly, all the heat generating portions 46 can be cooled efficiently.

The propulsion airflow F generated by the propeller 35 flows in the direction (rearward) in which the air flows in the cooling passage P (see FIG. 3). Accordingly, a portion of the propulsion airflow F flows into the cooling passage P, so that all the heat generating portions 46 can be cooled efficiently.

### Second Embodiment

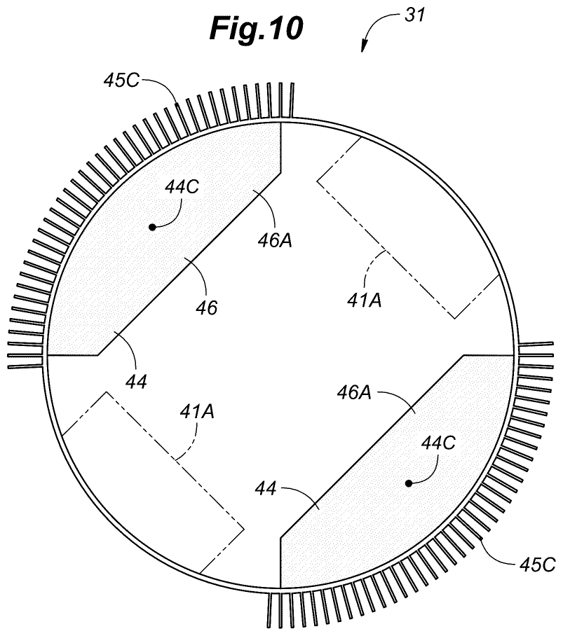

FIG. 10 is a cross-sectional view of the housing 41 of the first drive unit 31 according to a second embodiment. FIG. 10 corresponds to the cross-sectional view of FIG. 7 according to the first embodiment. As shown in FIG. 10, the driving device 16 according to the second embodiment is provided with a plurality of heat dissipation fins 45C passing through the heat receiving area HA, and is not provided with the auxiliary fins 45B. In the following description according to the second embodiment and a third embodiment, the same reference numerals are given to the same or similar components, and repetitive detailed descriptions will be omitted.

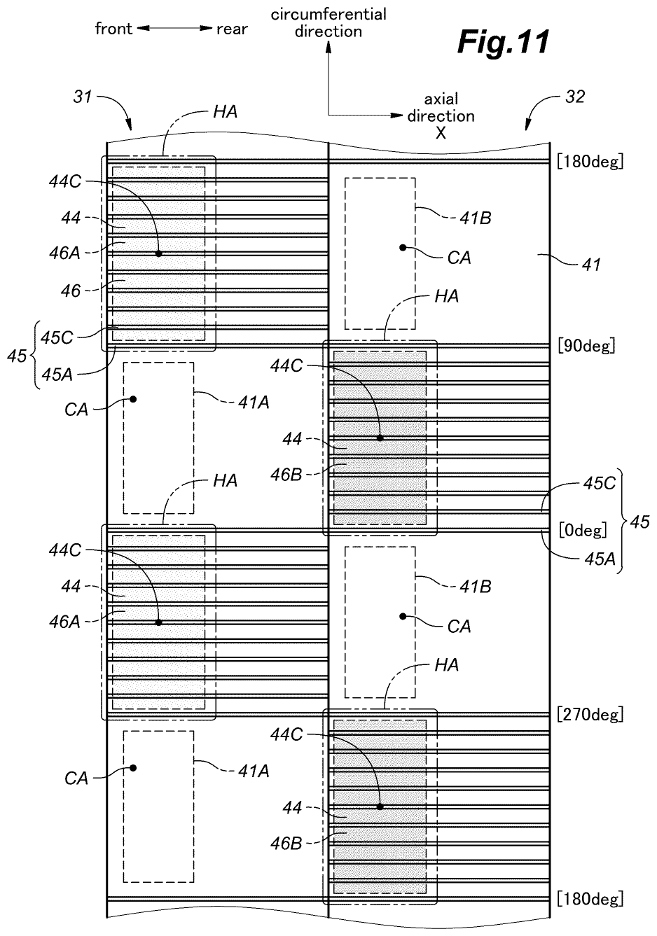

FIG. 11 is a development view of the housing 41 according to the second embodiment. As shown in FIGS. 10 and 11, each heat dissipation fin 45C is formed in a plate shape that extends radially outward of the housing 41 of the first drive unit 31 or the second drive unit 32, and extends continuously in the axial direction X from one end to another end of the housing 41. Each heat receiving area HA is provided with the heat dissipation fin 45C that passes through the heat receiving area HA. The heat dissipation fin 45C can promote cooling of the heat generating portions 46 adjacent to the heat receiving area HA. Accordingly, all the heat generating portions 46 can be cooled efficiently.

### Third embodiment

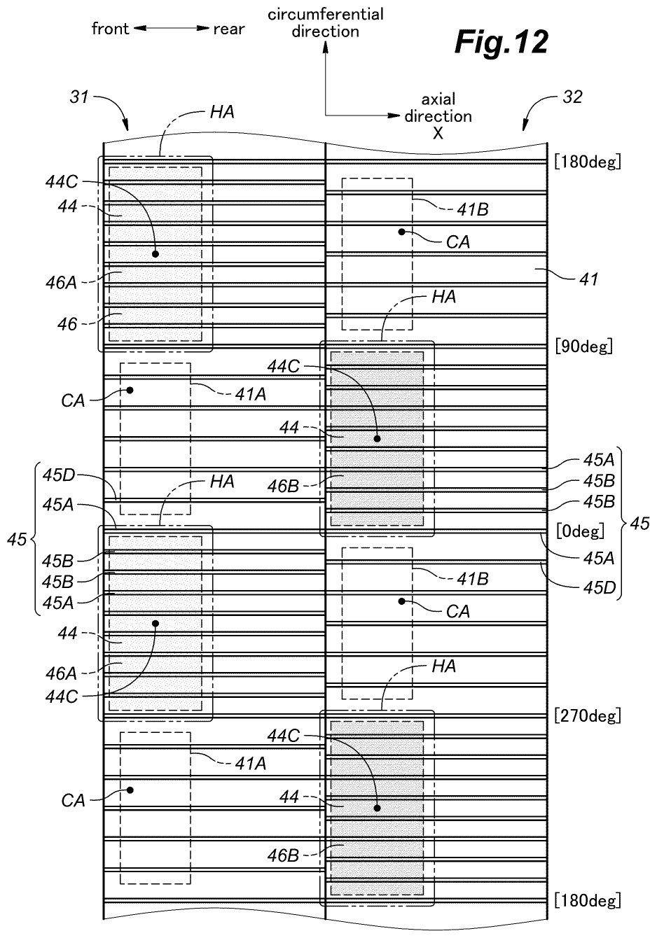

FIG. 12 is a development view of the housing 41 according to a third embodiment. The driving device 16 according to the third embodiment includes a plurality of heat dissipation fins 45D that are provided between the two adjacent guiding fins 45A and do not pass through the heat receiving area HA. Each heat dissipation fin 45D is formed in a plate shape that extends radially outward of the housing 41 of the first drive unit 31 or the second drive unit 32, and extends continuously in the axial direction X from one end to another end of the housing 41. In the first embodiment, one auxiliary fin 45B is provided between the two adjacent guiding fins 45A. In the present embodiment, the two auxiliary fins 45B and one heat dissipation fin 45D are provided between the two adjacent guiding fins 45A.

Between the two adjacent guiding fins 45A, the number of the auxiliary fins 45B is greater than the number of the heat dissipation fins 45D. Accordingly, the density of the heat dissipation fins 45 in the heat receiving area HA is higher than the density of the heat dissipation fins 45 in the non-heat receiving area CA. Accordingly, the heat generating portion 46 adjacent to the heat receiving area HA can be cooled efficiently, and therefore all the heat generating portions 46 can be cooled efficiently.

This concludes the description of the specific embodiments, but the present invention is not limited to the above embodiments or modifications, and can be widely modified and implemented. For example, the driving device 16 is not required to include the propeller 35. The propeller 35 is configured to rotate integrally with the shaft 34 according to the rotation of the shaft 34, thereby generating the propulsion airflow F (see FIG. 3) that flows along the axial direction X (rearward), but the direction of the propulsion airflow F is not limited to the rearward direction. For example, the propeller 35 may be configured to generate the propulsion airflow that flows along the forward direction. Further, there is no restriction on the orientation of the driving device 16.

In the first to third embodiments, air is used as the refrigerant, but the refrigerant can be any fluid. The refrigerant can be a gas or a liquid. Further, the electric motor 43 need not be a three-phase AC motor of an inner rotor type. The housing 41 and the duct 42 are formed in a cylindrical shape. The housing 41 may have a polygonal tubular shape such as a hexagonal tube. The duct 42 may have a polygonal tubular shape, such as a hexagonal tube.

In the first to third embodiments, the controller 44 is used as the heat generating portion 46. The devices corresponding to the heat generating portion may be changed. The three power modules (the power modules 55A to 55C) of the controller 44 may be the heat generating portions. In this case, the three power modules (the power modules 55A to 55C) may be arranged at equal intervals in the circumferential direction. In this case, the first drive unit 31 and the second drive unit 32 of the driving device 16 according to the first to third embodiments may each have only one controller 44. Further, there is no limitation on the number of controllers 44 included in the first drive unit 31 and the second drive unit 32. For example, the first drive unit 31 may have three or more controllers 44. The second drive unit 32 may have three or more controllers 44.

The guiding fin 45A, the auxiliary fin 45B, the heat dissipation fin 45C and the heat dissipation fin 45D are formed in a plate shape that extends in the axial direction X. The heat dissipation fins 45 may not be provided. Further, a heat dissipation fin having a shape different from that of the heat dissipation fin 45 may be provided. The heat dissipation fin may have any shape as long as the fin extends radially outward of the housing 41. For example, the heat dissipation fin may be cylindrical, prismatic, conical, or pyramidal, extending radially outward of the housing 41.

1. A driving device comprising a rotation shaft and configured to drive the rotation shaft, the driving device comprising:
a cooling passage formed on an outer circumference and extending along an axial direction of the rotation shaft; and
a plurality of heat generating portions arranged adjacent to the cooling passage, wherein
the plurality of heat generating portions includes at least one first heat generating portion and at least one second heat generating portion spaced apart from the first heat generating portion in the axial direction, and
the plurality of heat generating portions is arranged so that centers thereof do not overlap with each other when viewed in the axial direction.

2. The driving device according to claim 1, wherein each of the plurality of heat generating portions includes a plurality of heat generating elements, and the plurality of heat generating portions is arranged at equal intervals in a circumferential direction when viewed in the axial direction.

3. The driving device according to claim 1, further comprising a plurality of electric motors configured to drive the rotation shaft, and a plurality of controllers configured to generate heat when energized to control operation of the plurality of electric motors, wherein
the plurality of heat generating portions includes the plurality of controllers.

4. The driving device according to claim 1, wherein the at least one first heat generating portion comprises a plurality of first heat generating portions, and the at least one second heat generating portion comprises a plurality of second heat generating portions,
the plurality of heat generating portions includes the plurality of first heat generating portions and the plurality of second heat generating portions spaced apart from the plurality of first heat generating portions in the axial direction,
the plurality of first heat generating portions is arranged at equal intervals in a circumferential direction, and
the plurality of second heat generating portions is arranged at equal intervals in the circumferential direction.

5. The driving device according to claim 1, wherein each of the plurality of heat generating portions is arranged so as not to overlap with each other when viewed in the axial direction.

6. The driving device according to claim 1, wherein the cooling passage includes heat receiving areas adjacent to the plurality of heat generating portions and non-heat receiving areas adjacent to the heat receiving areas in a circumferential direction, and
each of the heat receiving areas is provided with a plurality of heat dissipation fins.

7. The driving device according to claim 6, wherein each of the heat receiving areas and each of the non-heat receiving areas are provided with the plurality of heat dissipation fins, and
density of the heat dissipation fins in each of the heat receiving areas is greater than the density of the heat dissipation fins in each of the non-heat receiving areas.

8. The driving device according to claim 6, wherein the plurality of heat dissipation fins includes a plurality of guiding fins that extends radially outward of the driving device and extends continuously in the axial direction from one end to another end of the driving device.

9. The driving device according to claim 8, wherein, in each of the heat receiving areas, at least one auxiliary fin is provided between the two adjacent guiding fins, and length of the auxiliary fin in the axial direction is shorter than length of the guiding fins in the axial direction.

10. The driving device according to claim 1, further comprising a propeller fixed to the rotation shaft and configured to generate a propulsion airflow that flows in a direction in which a refrigerant flows in the cooling passage.

11. An electric device comprising:
a cooling passage formed on an outer circumference and extending along a first direction; and
a plurality of heat generating portions arranged adjacent to the cooling passage, wherein
the plurality of heat generating portions includes at least one first heat generating portion and at least one second heat generating portion spaced apart from the first heat generating portion in the first direction, and
the plurality of heat generating portions is arranged so that centers thereof do not overlap with each other when viewed in the first direction.
